(19) United States
(12) Patent Application Publication
(10) Pub. No.: US 2023/0375279 A1
(43) Pub. Date: Nov. 23, 2023

(54) Apparatus and Methods for Coolant Distribution

(71) Applicant: Seguente, Inc., Melbourne, FL (US)

(72) Inventors: John Kim, Bridgewater, NJ (US); Ryan Enright, Berkeley Heights, NJ (US); Raffaele Luca Amalfi, Melbourne, FL (US)

(21) Appl. No.: 18/209,752

(22) Filed: Jun. 14, 2023

Related U.S. Application Data
(63) Continuation-in-part of application No. 18/198,522, filed on May 17, 2023.
(60) Provisional application No. 63/344,291, filed on May 20, 2022.
(60) Provisional application No. 63/352,224, filed on Jun. 15, 2022.

(51) Int. Cl. F28D 15/06; F28D 15/02

(52) U.S. Cl. CPC F28D 15/06; F28D 15/025; F28F 2265/16; F28D 2021/0029

(57) ABSTRACT

Systems, devices, and methods for providing a passive coolant distributions unit (pCDU) to promote refrigerant flow circulation, manage and monitor refrigerant inventory in a closed loop system.

### CROSS REFERENCE TO RELATED APPLICATIONS

This application is a Continuation-In-Part of U.S. patent application Ser. No. 18/198,522 filed May 17, 2023 which claims the benefit of priority to U.S. Provisional Application Ser. No. 63/344,291 filed May 20, 2022, and this application claims the benefit of priority to U.S. Provisional Patent Application Ser. No. 63/353,224 filed Jun. 17, 2022. The entire disclosure of each of the applications listed in this paragraph are incorporated herein by specific reference thereto.

### FIELD OF INVENTION

This invention relates to passive coolant distribution units (pCDU), and in particular apparatus, devices, systems, and methods for providing a passive coolant distributions unit (pCDU) to promote refrigerant flow circulation, manage and monitor refrigerant inventory in a closed loop system.

### BACKGROUND AND PRIOR ART

Anthropogenic gas emissions are shifting the Earth's global energy balance, thereby resulting in climate change. By 2050, global warming is estimated to result in one-third of the animal and plant species to extinction, while inevitably shaving 11-14% off global economic output, which equates to approximately 23 trillion dollars. See Swiss Re Institute April 2021 report. https://www.swissre.com/dam/jcr:b257cfe9-68e8-4116-b232-a87949982f7c/nr20210421-ecc-publication-en.pdf

To combat these grim projections and to avoid irreversible economic and environmental consequences, countries have introduced carbon credit to incentivize enterprises to reduce or capture carbon emissions.

Despite strong economic incentives to lower carbon emission, most data centers and telecom central offices are designed and still operate with air-cooling technologies, and their energy consumption to cool hardware equipment is on average 40% of the total energy consumed in the facility. Furthermore, the waste heat is in the form of hot air with low energy density, which requires costly air handling systems and infrastructure upgrades to utilize that heat for other applications.

With growing awareness of social responsibility to combat climate change, there is a global consensus for action to improve energy efficiency and reduce carbon emissions across all industries. Hence, it is extremely important to develop novel high-efficiency cooling technologies along with amenable heat capture/reuse technologies, which satisfy sustainability mandates as well as market adoption.

Moving away from conventional air-based cooling technology, liquid/refrigerant-based cooling technology, which has superior cooling performance compared to that of conventional air-based technology, is gaining traction. Herein, we disclose methods, systems, and apparatus to optimize novel cooling systems to achieve next-level thermal performance while reaching sustainability goals through smart energy management solutions.

Heat Exchangers in Coolant Distribution Unit (PDU) for Liquid Cooling

A heat exchanger is part of a liquid-based electronics cooling system. In implementations, a heat exchanger is enclosed together with a pump unit that is fluidically coupled with a heat exchanger. A pump unit that drives coolant throughout a cooling system and removes heat from electronic equipment. Depending on the system implementation, the heat exchangers can reject the heat to air or liquid.

For example, U.S. Pat. No. 9,668,382 to Steinke et al., which is incorporated by reference, discloses a coolant distribution unit for a multi-node chassis. In this implementation, an air-to-coolant heat exchanger is in fluid communication between the inlet conduit and the outlet conduit, and a pump circulates a coolant throughout the system.

Similarly, U.S. Pat. No. 8,297,069 to Novotny et al., which is incorporated by reference discloses a coolant distribution unit comprising a liquid-to-liquid heat exchanger and a pump that drives a coolant in the system.

Invariably a heat exchanger for liquid cooling system requires at least one pump to drive a coolant. Features that enable pumpless coolant distribution unit however are not disclosed.

IoT System/Subsystem Implemented for Managing Infrastructure and Improving Overall Efficiency

IoT devices are becoming a technology of choice to help enterprises reduce carbon emissions by adding intelligence to optimize operations. Increasingly important to sustainable industrial practice, the global IoT market is projected to reach 3.9 trillion to 11.1 trillion by 2025. See https://www.mckinsey.com/˜/media/McKinsey/Business%20Functions/McKinsey%20Digital/Our%20Insights/The%20Internet%20of%20Things%20How%20to%20capture%20the%20value%20of%20IoT/How-to-capture-the-value-of-IoT.pdf

In essence, IoT devices are network-enabled hardware that can transmit/receive data over the internet, and they can be embedded into a wide range of industrial equipment, sensors, actuators, or appliances to optimize industrial processes. Recent advances in cloud-based technology and machine learning (AI/ML) are being seamlessly integrated with IoT devices to execute autonomous tasks and provide intelligent analytics. Along with advances in 5G technology, IoT devices will lead the paradigm shift towards sustainable Industry 4.0 ecosystem, which encompasses holistic smart manufacturing, supply chain management based on big data to achieve sustainability targets.

Liu and others (See Q Liu, et. al., Green data center with IoT sensing and cloud-assisted smart temperature control system, Computer Networks, Volume 101, 2016) disclosed a method to build green data centers utilizing remote sensor networks (FIG. 3). The system architecture consists of a temperature control system and cloud management platform. The temperature control system provides cooling, ventilation, environment signal acquisition and transmission, whereas the cloud management platform is responsible for data storage and query, data monitoring, accessory device management, and Big Data-based system evaluation.

Similarly, Evans et al. disclosed methods, systems, and apparatus (See U.S. Pat. No. 10,643,121 to Evans et al., which is incorporated by reference) for improving operational efficiency within a data center by modelling data center performance and predicting power usage efficiency (FIG. 4). The state data (140) from FIG. 4 include temperatures, power, pump speeds, and set points all of which could be accessible via IoT devices.

A group from Chengdu Qinchuan Technology Development filed a patent application (See China Patent 102496209 to Zehua Shao titled Intelligent object network heat meter and management system.

The patent application discloses methods, systems and apparatus that are simple in structure, functionally realized based on the technique of internet of things, suitable for being mounted and used in various areas, and wide in application range. In essence, this is an IoT-enabled heat meter comprising a CPU controller, temperature, and flow measurement apparatus.

U.S. Pat. No. 8,706,308 to Reichmuth et al., which is incorporated by reference, disclosed methods, systems, and apparatus comprising one or more energy load meters coupled with a facility's energy supply system. The invention enables accurate modelling of past and future use, measuring current use and savings, diagnosing current problems, and making adjustments where sensible, and monetizing energy savings.

U.S. Pat. No. 10,328,408 to Victor et al., which is incorporated by reference, disclosed methods, systems, and apparatus comprising a heat exchanger along with many other components in chemical/petrochemical plants and one or more sensors associated with the heat exchanger.

A plant or refinery may include equipment such as reactors, heaters, heat exchangers, regenerators, separators, and others. Types of heat exchangers include shell and tube, plate and shell, plate fin, air cooled, wetted-surface air cooled, and others. Operating methods may impact deterioration in equipment condition, prolong equipment life, extend production operating time, or provide other benefits. Mechanical or digital sensors may be used for monitoring equipment, and sensor data may be programmatically analyzed to identify developing problems. For example, sensors may be used in conjunction with one or more system components to detect and correct maldistribution, cross-leakage, strain, pre-leakage, thermal stresses, fouling, vibration, problems in liquid lifting, conditions that can affect air-cooled exchangers, conditions that can affect a wetted-surface air-cooled heat exchanger, etc. An operating condition or mode may be adjusted to prolong equipment life or avoid equipment failure.

The use of IoT devices, cloud technology, AI and machine learning for system-level monitoring and optimization is pervasive in open literature. For example, U.S. Pat. No. 11,416,739 to Qin, which is incorporated by reference, discloses a simulation model based on conditions associated with a building infrastructure to optimize the overall energy efficiency.

None of the above prior art discloses enabling features to build a coolant distribution system supporting active and passive two-phase, and liquid-base, cooling systems. Also, none of the above prior art discloses a system that provides information related to the amount of waste thermal energy being captured from ICT systems from a coolant distribution system. Furthermore, none of the prior art discloses methods, systems, and apparatus to obtain data from multiple cooling systems collectively to enable holistic understanding of the overall system. These enabling features will incentivize data centers and telecom operators to adapt the disclosed invention to achieve sustainability targets.

The prior art does not disclose hardware and software design features that are critical to build a passive coolant distribution unit (pCDU), which is extremely challenging without pumps that drive flow circulation in a thermosyphon loop. Implementing passive coolant distribution unit requires numerous novel features.

Thus, the need exists for solutions to the above problems with the prior art.

### SUMMARY OF THE INVENTION

A primary objective of the present invention is to provide a passive coolant distribution unit (pCDU), and in particular apparatus, devices, systems, and methods for providing a passive coolant distributions unit (pCDU) to promote refrigerant flow circulation, manage and monitor refrigerant inventory in a closed loop system.

A secondary objective of the present invention is to provide passive coolant distribution unit (pCDU) that is designed to promote refrigerant flow circulation, manage and monitor refrigerant inventory in the closed loop system, reject heat to the facility service lines, such as chilled water or any other air/liquid loop, and collect data using IoT-based sensor technology and analytics.

The invention provides a promising thermal energy management approach is the extension of passive two-phase heat transfer to rack scale. Thermosyphon loops (TL) coupled with high-performance evaporators and condensers enable a scalable rack cooling system that operates with high thermal performance. This is achieved without the need for active pumping/control and operates within a hybrid cooling paradigm complimenting the significant investment in current air-cooling technology. This cooling technology provides key differentiators with quantifiable advantages including higher revenue for datacenter/telecom operators, significant cooling energy reduction, lower carbon footprint, higher reliability, easy serviceability, zero-maintenance using eco-friendly, low-cost cooling fluids, extended product life cycle and ease of implementation into existing and new datacenter/telecom sites.

Furthermore, passive two-phase cooling technologies, using zero ozone depleting potential, low global warping potential refrigerants as working fluids, provide excellent key metrics (e.g., heat density, efficiency, reliability, sustainability etc.) and represent a viable, long-term solution with regards to hardware densifications and thermal performance required by next-generation telecommunications and computing environments. It is also extremely important that cooling technology is highly efficient, which will address positive environmental & sustainability (ESG) requirements, for wider technology adoption.

Two-phase cooling systems can be implemented in passive mode (e.g., thermosyphons where gravity/buoyancy is the driving force) or in active mode with mechanical drivers (e.g., pump(s) allowing for fluid flow circulation). Here, we disclose features for a (semi)passive coolant distribution unit, which can be adapted for both active and passive two-phase cooling systems.

This patent application discloses a passive coolant distribution unit (pCDU) that is designed to promote refrigerant flow circulation, manage and monitor refrigerant inventory in the closed loop system, reject heat to the facility service lines, such as chilled water or any other air/liquid loop, and collect data using IoT-based sensor technology and analytics. Data stream from pCDU can assist end users to monitor, manage, optimize, and detect anomalies during the operation of thermal management systems. In one implementation, users can quantify energy flows from the hardware being cooled to the secondary heat rejection side to address sustainability needs by tracking capture efficiency, heat rejection temperature and CO₂ footprint. F-gas accounting system whereby the system collects and stores data regarding the system refrigerant charge. System interlock that requires the servicing technician to input charge mass during initial charging and any subsequent re-filling.

The prior art does not disclose hardware and software design features that are critical to build a passive coolant distribution unit (pCDU), which is extremely challenging without pumps that drive flow circulation in a thermosyphon loop. Implementing passive coolant distribution unit requires numerous novel features.

An embodiment of a passive coolant distribution unit (pCDU) system, that includes: a heat exchanger, a coolant distribution manifold, a fluid inventory management system between the heat exchanger and the coolant distribution manifold, for allowing condensed liquid to accumulate in a fluid inventory storage unit, a supplementary positive displacement pump downstream to the fluid inventory storage unit, and sensors selected from at least one temperature sensor and at least one pressure sensor, the sensors providing a feedback loop for maintaining a liquid level in the fluid inventory storage unit.

The system can further include a chassis for housing the pCDU system, the chassis having detachable brackets for installing the chassis adjacent to a computer server rack.

The system can further include a second coolant distribution manifold, and quick connects for adding the second coolant distribution manifold to the passive coolant distribution unit (pCDU) system.

The system can further include a pump unit for providing a thermosyphon loop in the system.

The pump unit can be installed fluidically in parallel to a main liquid coolant flow path in the system.

The system can further include a backflow preventer to stop pumped liquid from returning to the fluid inventory storage unit.

The fluid inventory management system can include a level sensor that ensures coolant level is maintained at a selected level, to prevent fluid cavitation in the pump unit.

The fluid inventory management system can include a modular and stackable liquid accumulator.

The system can further include a reserve tank fluidically connected to the fluid inventory management system, and a valve for allowing coolant fluid to be transported to a main accumulator in the fluid inventory management system.

The system can further include a leak detection monitor, for detecting sudden drop in temperature from temperature sensors in the system, which constitutes a major leak, and a safety isolation valve triggered by the leak detection monitor to contain coolant from leaking out.

The system can further include a leak detection monitor for detecting data from chemical sensors for detecting coolant leak from the system, the chemical sensors, selected from at least one of metal oxide, Infrared, and MEMS-based sensors, the chemical sensors are useful to detect minor leaks which include small leaks (mostly due to diffusion of coolant molecules through polymer seals) that does not immediately affect overall system performance.

The system can further include a control module for actuating an isolation valve when a major leak, which includes a sudden drop in temperature is detected in the system to contain coolant from leaking out, and an emergency alert generated from the control module to inform system operators of the major leak detection to provide a shut down of the system.

The system can further include an air ingress management control for separating air ingresses into the system, and accumulating the separated air ingresses into a second fluid inventory storage unit.
The system can further include a prediction controller to estimate CPU (Central Processing Unit) heat load based on PDU (Power Distribution Unit), wherein the prediction controller is used when data from IT equipment is not accessible.
The system can further include a pump control system that optimizes pump speed based on predicted coolant mass flow rate, which is derived from machine learning model using input features from at least one of IT equipment and a PDU (Power Distribution Unit).

The system can further include data collected from a PDU (Power Distribution Unit) and the heat exchanger to calculate rack-level heat capture efficiency, and storage of the data in a database for storing energy in an out of the system for an end-user to monitor and account for carbon offset credit (sustainability accounting).

The system can further include server start-up detection and heater block starter feature

The system can further include flow stabilization methods during start-up (with PCDU)

The system can further include load balancing in heat reuse applications, where the demand load fluctuates in time, to ensure sufficient heat rejection from the target equipment to be cooled, e.g., IT equipment, servers.

The system can further include a water leak detection monitor, for detecting accidental water leaks in or around a heat exchanger.

Further objects and advantages of this invention will be apparent from the following detailed description of the presently preferred embodiments which are illustrated schematically in the accompanying drawings.

### BRIEF DESCRIPTION OF THE FIGURES

The drawing figures depict one or more implementations in accord with the present concepts, by way of example only, not by way of limitations. In the figures, like reference numerals refer to the same or similar elements.

FIG. 1 shows the overall system architecture of a passive coolant distribution unit (pCDU), for the subject invention.

FIG. 2 shows an outside location of the pCDU unit relative to computer servers.

FIG. 3 shows detachable hardware for mounting a pCDU chassis.

FIG. 4 shows layout for connecting a pCDU with a coolant distribution unit and servers.

FIG. 5 shows a layout for connecting a pCDU with coolant distribution manifold and servers.

FIG. 6 shows a representative implementation of a ‘hybrid” active/passive pCDU system.

FIG. 7 shows an additional control system for the pCDU used for pump assisted gravity.

FIG. 8 shows an alternative control system with a peripheral pump for the pCDU.

FIG. 9 is a side view of a liquid inventory management system for the pCDU.

FIG. 10 shows a modular fluid inventory system for the pCDU.

FIG. 11 shows a fluid inventory monitoring system for the pCDU.

FIG. 12 shows a fluid inventory management system for the pCDU. With a reserve tank for streamlined maintenance.

FIG. 13 shows a leak detection system for the pCDU. based on a live data stream from sensors

FIG. 14 shows a major leak response system for the pCDU.

FIG. 15 is a schematic of an air ingress management system for the pCDU.

FIG. 16 shows a schematic of a prediction model deployment for the pCDU.

FIG. 17 is a schematic of a conditional pump actuation process flow for the pCDU.

FIG. 18 shows a heat capture monitoring system for the pCDU.

FIG. 19 is a schematic of a feature that improves the thermosyphon-loop start up behavior for the pCDU.

FIG. 20 is a schematic representation of a server rack start up sequence for the pCDU.

FIG. 21 is a schematic for system optimization through heat load balancing on the secondary side for the pCDU.

### DESCRIPTION OF THE PREFERRED EMBODIMENTS

Before explaining the disclosed embodiments of the present invention in detail it is to be understood that the invention is not limited in its applications to the details of the particular arrangements shown since the invention is capable of other embodiments. Also, the terminology used herein is for the purpose of description and not of limitation.

In the Summary above and in the Detailed Description of Preferred Embodiments and in the accompanying drawings, reference is made to particular features (including method steps) of the invention. It is to be understood that the disclosure of the invention in this specification does not include all possible combinations of such particular features. For example, where a particular feature is disclosed in the context of a particular aspect or embodiment of the invention, that feature can also be used, to the extent possible, in combination with and/or in the context of other particular aspects and embodiments of the invention, and in the invention generally.

In this section, some embodiments of the invention will be described more fully with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will convey the scope of the invention to those skilled in the art. Like numbers refer to like elements throughout, and prime notation is used to indicate similar elements in alternative embodiments.

Other technical advantages may become readily apparent to one of ordinary skill in the art after review of the following figures and description.

It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below

Unless otherwise specifically noted, articles depicted in the drawings are not necessarily drawn to scale.

In a typical implementation, a passive coolant distribution unit consists of multiple sub-components, such as a heat exchanger with sensors for energy metering, two or more pairs of quick connects for making fluidic connections, fluid inventory management system, optional pump to supplement gravitational force for coolant circulation for coolant storage, IoT-system comprising sensors, microcontroller, firmware and network module for data processing and data input/output through the network, and back-end software to provide additional software features, such as data center monitoring and optimization.

A list of the components will be described.

A list of abbreviations in the application will now be defined.
AI Artificial Intelligence
API Application Programming Interface
BMC Baseboard Management Controller
BTU British Thermal Unit
pCDU passive Coolant Distribution Unit

A list of component numbers in the figures will now be described.
800 pCDU
801 Servers 801
802 coolant distribution manifold.
803 a pair of quick disconnectors for coolant.
804 fluid inventory management module.
805 Heat exchanger.
806 a pair of quick disconnectors for facility side coolant.
807 Facility heat rejection site.
808 Sensors.
809 MCU/Firmware.
810 Network Module.
811 Data center infrastructure management software.
812 Optional pump.
900 server rack
901 computer servers
902 coolant distribution unit
903 rack
904 rack installation
907 pCDU unit
1100 pCDU
1101 multiple servers
1102 coolant distribution unit
1103 second coolant unit
1104 pair of quick disconnectors
1105 pair of quick connectors that fluidically connects a pCDU with a second coolant distribution unit
1200 pCDU
1201 coolant distribution manifold
1202 servers
1203 pair of quick connectors
1205 redundant pair of quick connectors
1205 second pCDU
1301 heat exchanger
1302 “downcomer” pipe
1303 evaporator 1303
1304 “riser” pipe
1305 3-eay valve
1306 parallel fluidic path
1307 positive displacement pump unit
1308 backflow preventing device
1400 downcomer pipe
1401 temperature sensor
1402 controller
1403 positive displacement pump 1403
1404 branching point
1405 back-flow preventing device
1500 downcomer pipe
1501 peripheral pump
1502 pressure/temperature sensor unit
1503 controller unit 1503
1601 heat exchanger/condenser
1602 evaporators
1603 downcomer pipe
1604 riser pipe
1605 liquid accumulator—low level
1606 high level
1608 Optional pump unit
1700 metal plate
1701 pre-defined holes 1701
1702 second part 1702
1703 internal geometry 1703.
1704 metal port that defines port location (e.g., tapped or through holes)
1705 modular liquid accumulator
1706, 1707, 1708, 1709 ports
1800 IT equipment
1801 heat exchanger
1802 liquid accumulator
1803 sensor 1803.
1804 controller unit
1805 power distribution unit
1900 liquid level sensor
1901 IT equipment
1902 power distribution unit
1903 controller unit
1904 valve 1904
1905 a liquid reservoir to store coolant
1906 heat exchanger
1907 port
2000 Non-hermetically sealed system
2001 temperature sensors 2001
2002 chemical sensors 2002
2100 Major leak response system
2101 Control module
2102 isolation valve
2103 pCDU
2104 Emergency alert
2105 IT equipment
2200 liquid coolant reservoir
2201 second reservoir 2201
2202 downcomer pipe
2203 heat exchanger 2203
2204 upper access valve
2205 lower valve
2300 data center environment
2301 training data sets
2302 colocation data centers
2500 heat capture monitoring system
2501 heat exchanger
2502 heat metering module
2503 PDU (Power Distribution Unit)
2504 IT equipment
2505 power cables
2506 chilled water enters
2508, 2509, Temperature sensors
2510 flow meter
2600 pCDU
2601 heat exchanger
2602 control module
2603 PDU
2604 server rack 2604
2605 multiple servers
2606 downcomer pipe
2607 riser pipe
2608 heating element
2609 PDU power draw monitored
2700 server rack 2700
2701 PDU (Power Distribution Unit)
2702, 2703, 2704 three power banks
2705 bottommost server group
2706 middle server group
2707 last server group
2801 IT equipment racks
2802 primary cooling loop
2803 facility level secondary loop manifold
2804 automated valve
2805 heat reuse application
2806 liquid/liquid heat exchanger
2807 variable speed pumped dry cooler loop 2807

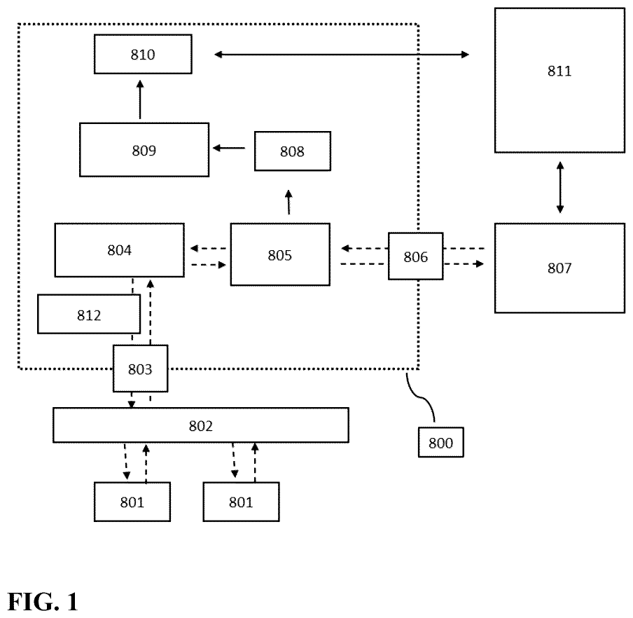

FIG. 1 shows the overall system architecture of a passive coolant distribution unit (pCDU) 800, for the subject invention. Referring to FIG. 1, The pCDU 800 is fluidically connected to coolant distribution manifold and building facility via quick connectors.

### Heat Exchanger (Condenser) 805

The main function of a heat exchanger 805 is to transfer heat from IT equipment to facility-level cooling infrastructure. Heat exchanger technology can include, plate heat exchangers, tube-in-tube heat exchangers, shall and tube heat exchangers or any other type of heat exchanger.

A passive coolant distribution unit requires extra care when sizing the heat exchanger 805 to ensure pressure drop is not prohibitively high for passive coolant circulation.

When forming a fluidic connection between the heat exchanger 805 with a flow distribution unit (i.e., manifold) 802, pressure drop across connecting pipes/tubes should be carefully designed in a passive thermosyphon system to ensure excessive pressure drop does not negatively impact the flow circulation.

To ensure proper flow circulation with desired direction, tubing/hose diameter with different sizes can be used to make fluidic connection between the heat exchanger 805 and rest of the system. A heat exchanger 805 can be equipped with additional sensors 808, such as temperature measuring probes and flow meters to measure amount of energy flow through the heat exchanger.

Referring to FIG. 1, a pair of quick connectors 803 fluidically connect a coolant distribution manifold 802 and a fluid inventory management module 804.

### Charging Port & Quick Connect

A port (e.g., Schrader valve) for charging or evacuating coolant could be introduced in any location along the tubing or hose within or outside of an enclosure. Quick connects for easily making or breaking fluidic connection can be installed on or outside of an enclosure for easy installation. In a typical implementation, there would be a pair of quick connectors for coolant side and a second pair of quick connectors for facility coolant side (e.g., chilled water line). Optionally, additional pairs of quick connects can be implemented to expand the cooling system in a modular fashion.

### Fluid Inventory Management System 804

A cubical, rectangular, or irregular shaped container with mechanical specifications that allows storage of coolant storage is installed inside a pCDU enclosure. In a typical implementation, a fluid inventory management system 804 is installed between a heat exchanger 805 and a coolant distribution manifold 802 in such a way that condensed liquid accumulates in the fluid inventory storage unit instead of stagnating inside a heat exchanger 805.

### Optional Pump System 812

A pump unit, such as a positive displacement pump, can be optionally added to the system inside an enclosure of pCDU system. The pump unit is installed downstream of a liquid accumulator to ensure the inlet side of the pump unit is always in liquid phase. In a typical implementation, a pump unit is fluidically connected in parallel to the rest of the system, and mechanical displacement of a coolant supplements gravitational driving force that drives coolant circulation. Additional features may include passive/active hydraulic components to prevent backflow in the system. During operation, a pump unit can stay dormant to save energy, and a pump is only activated when supplemental driving force is encouraged to improve the overall performance of a cooling system. A control loop mechanism may be implemented to further optimize the system operation.

### Microcontroller (MCU) 809 and Sensors 808

A microcontroller is a central component that orchestrates a data streaming process. In a typical implementation, several modules, such as power module, network modules, energy metering modules, and analog/digital circuits enabling temperature sensors and mass flow meters are populated on a same PCB with a microcontroller chip.

The PCB can have multiple I/O ports for sensor heads/probes that can provide accurate measurements, which in turn can be processed in the microcontroller and exposed for end users via standard data transfer protocol, such as HTTP API or SNMP.

In a typical implementation the pCDU system can be equipped with a network module that enables wired (e.g., Ethernet) and/or wireless connectivity (e.g., WIFI or BLE) to the local/remote network. The microcontroller can be flashed with a firmware that can be updated with manual programming or updated remotely Over-the-Air (OTA). One of major functions of the firmware is hosting a webserver that allows end users to provision the pCDU.

### Backend Software Service

Backend software for pCDU could provide a system monitoring platform, which can include a GUI based dashboard for visualizing real-time data streams. The backend database can communicate with a machine learning module to provide further analytic insights, such as projections, estimates, or predictions, all of which can be derived based on sensor measurements from single or multiple pCDU units.

It is important to monitor hydraulic and thermal performance of a liquid cooling system for electronics cooling application. In a mission critical infrastructure (i.e., data centers), real-time monitoring and anomaly detection is critical to minimize system down time and early maintenance. It is even more critical in a passive coolant distribution system (i.e., gravity driven thermosyphon loop) to have real-time telemetry to ensure robust coolant circulation within the system without a pump unit.

In a representative implementation, a pCDU hardware will have a unique identifier in such a way that each pCDU hardware can become a node in a local area network.

Through this local network, sensor readings and other industry standard data stream sources, such as Redfish, IPMI or SNMP can be ingested for backend software features. Optionally, these datasets can be pre-processed and packaged to payloads in JSON format, which in turn is wirelessly broadcast via standard IoT protocols (e.g., MQTT, AMQP, WebSocket etc.).

Payloads ultimately reaches a local or cloud server for further data consumption and analytics. Light-weight analytics could be done on a microcontroller-layer (e.g., embedded AI/ML Artificial intelligence and Machine Learning), while more complex analysis would be typically carried out at the backend.

The backend software ingests data stream from pCDU as well as other IT equipment to analyze the operational status of a data center, such as temperature or energy usage.

Software features based on real-time telemetry data can be integrated with other software platforms such as data center infrastructure management (DCIM) software. Furthermore, a software feature can analyze the data and update operational parameters in a data center accordingly to maximize the overall energy efficiency, or any other relevant figure of merit (FoM) of the system.

Detachable Universal Installation Hardware

To take advantage of gravitational force for driving coolant circulation, a passive coolant distribution unit (pCDU) is installed above IT equipment.

A chassis including various sub-components such as a heat exchanger, sensors, microcontroller, metering modules, and quick connectors, can be mounted across various locations above IT equipment.

For example, a chassis can be installed inside a server rack (rack-mount), on top of a server rack (top of the rack), on a structural ceiling (above the rack), inside plenum space (remote installation), or even on a building roof.

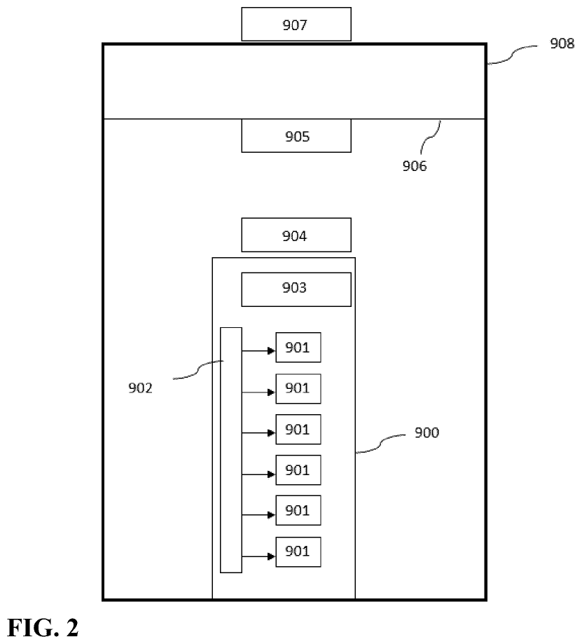

FIG. 2 shows an outside location of the pCDU unit 907 relative to computer servers 901. A pCDU unit 907 can be deployed in various locations. A server rack 900 with multiple servers 901 with a coolant distribution unit 902.

For rackmount deployment, a pCDU 907 can be installed at the highest point within the rack 903. Placing the chassis outside of the rack 903 would enable IT operators to add more computing units to maximize the compute density in the server rack 903. Also moving the coolant distribution unit outside of the IT envelope removes facility side chilled water to a remote location. Above the rack installation 904 is attached to a server rack 900.

A remote pCDU 905 can be installed on a suspended ceiling structure, such as Unistrut 906 to utilize the space above server racks 900. A rooftop pCDU 907 can be placed outside of a data center building 908.

To ensure a pCDU chassis is pre-designed to accommodate flexible deployment scenarios, threaded holes and mounting accessories can be mounted across multiple locations throughout the chassis.

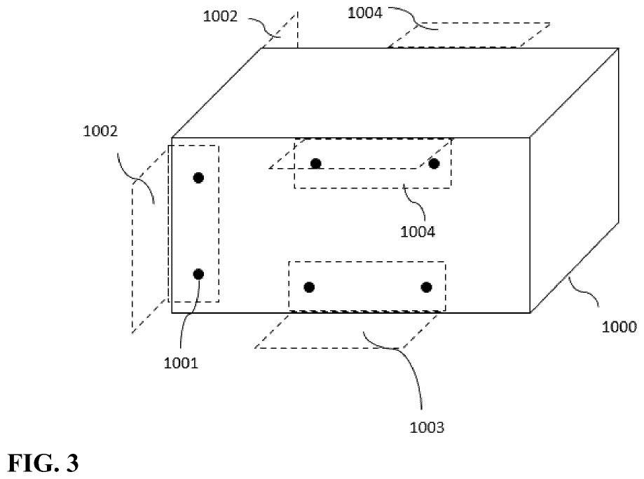

FIG. 3 shows detachable hardware for mounting a pCDU chassis 1000.

The invention can make use of detachable universal hardware for flexible deployment and installation of pCDU (1000). A pCDU chassis 1000 can have multiple tapped screw holes 1001 for detachable mounting hardware 1002, 1003, and 1004.

For rack-mount installation, mounting brackets 1002 can be installed on the side of a pCDU chassis. For installation using suspended ceiling structure, a pCDU can hang on a rigid structure via a bracket 1004. For above the rack or top of the roof installation, a bracket 1003 can be installed.

### Modular Deployments

IT equipment in data centers continuously undergoes refresh cycles to upgrade computational capability. A liquid based cooling system would have to be flexible to accommodate these continuous changes, while minimizing server downtime arising from refrigerant recovery, charging, and rearranging fluidic connections.

One of the strategies to minimize such downtime is to avoid having to recover refrigerants when only a subcomponent, such as a coolant distribution manifold, needs to be replaced due to increased power output requirements. This can be achieved by having a second set of quick connect couplings on a pCDU.

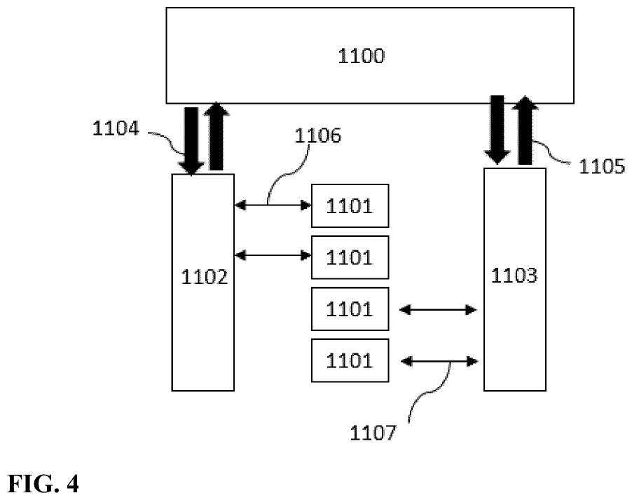

FIG. 4 shows layout for connecting a pCDU with a coolant distribution unit and servers.

A pCDU 1100 can be provisioned with multiple servers 1101, a coolant distribution unit 1102 and a pair of quick disconnectors 1104 all of which are fluidically connected. For ease of maintenance and second pair of quick connectors. A redundant manifold can be installed during server operation. Once all servers are connected to a new coolant distribution manifold, the old manifold can be removed. This procedure minimizes server downtime during this manifold replacement operation.

Similarly, when the system requires a heat exchanger with a bigger capacity, a second pCDU can be added through the second pair of quick connect to increase the capacity.

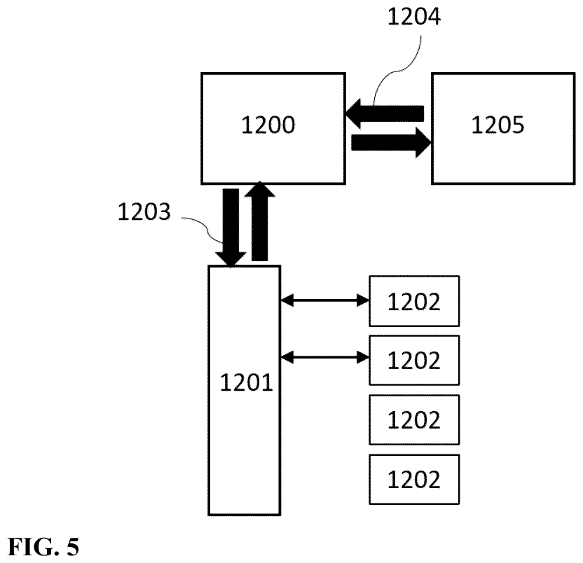

FIG. 5 shows a layout for connecting a pCDU 1200 with a coolant distribution manifold 1201 and servers 1202.

A pCDU 1200 can be fluidically connected with a coolant distribution manifold 1201 and multiple servers 1202. The first pair of quick connectors 1203 are used for making connection between a pCDU 120 and a coolant distribution manifold 1201. A redundant pair of quick connectors 1204) can be used for adding a second pCDU 1205 for increasing cooling capacity or increasing internal volume for increased coolant storage capacity in the thermosyphon loop system. Multiple pCDU units can be daisy-chained.

### Pump-Assisted Gravity Driven Coolant Flow

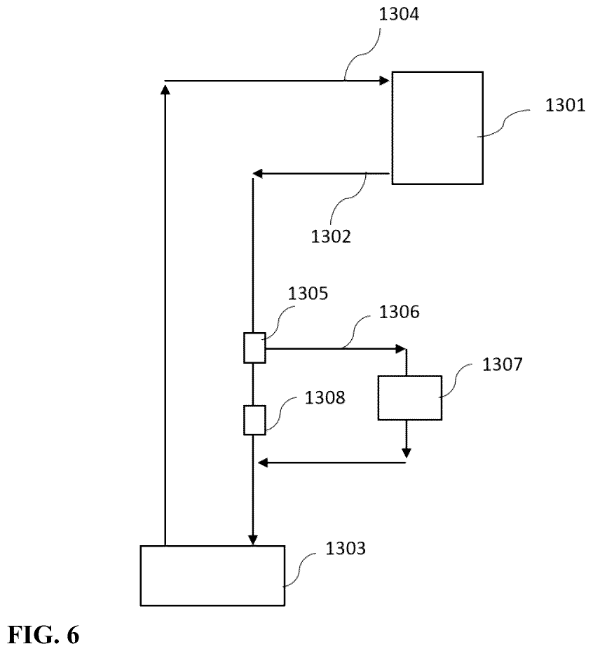

FIG. 6 shows a representative implementation of a ‘hybrid” active/passive pCDU system.

With reference to FIG. 6, a supplementary pump can be added to the coolant distribution unit to further enhance the coolant circulation in the system.

In a typical implementation, a liquid accumulator installed at the outlet side of a heat exchanger, where excess liquid is stored and maintained for providing hydraulic static pressure. This hydrostatic pressure is primarily responsible for driving the coolant circulation inside a thermosyphon loop based system. Having a liquid accumulator also prevents entrainment of gas-phase coolant from entering a pump unit that has negative impact.

A positive displacement pump can be installed in parallel at the outlet of liquid accumulator, which will ensure that a pump will always receive liquid with substantial inlet pressure to prevent cavitation.

When a positive displacement pump is not active, the hydraulic path through the pump is closed, and all liquid will flow through a bypass. When a pump is inactive, coolant circulation can be solely driven by gravity in a thermosyphon based system (“gravity only mode”). Once a pump is turned on and becomes active, liquid flow will be driven by gravity as well as mechanical force. In a typical implementation, the liquid bypass requires a backflow preventing mechanism to stop pumped liquid from returning to the liquid accumulator and the pump suction side. A passive component, such as a check-valve, or an active component, such as a three-way valve or solenoid valve can be deployed to achieve the required functionality.

Referring to FIG. 6, a heat exchanger 1301 provides condensed coolant in liquid phase through a “downcomer” pipe 1302. The coolant flows through an evaporator 1303 and liquid vapor mixture enters a heat exchanger through a “riser” pipe 1304.

A branching point, which can be a simple tee or a 3-way valve, 1305 can be added to the downcomer to create a parallel path 1306. A pump unit, for example a positive displacement pump unit, 1307 can be installed in-line with the parallel fluidic path 1306.

When pump unit 1307 is turned off, a parallel fluidic path along 1306, 1307 is blocked and coolant is driven only by gravity. When a pump becomes active, coolant flows through the pump via pump-assisted gravity driven flow.

To prevent undesired backflow, a backflow preventing device 1308 can be added to the system. The back flow preventing device can be an active on/off valve, or passive device, such as check valve with low activation pressure differential. Alternatively, a branching point 1305 can be a 3-way valve that can be actuated with external trigger.

### Additional Control System

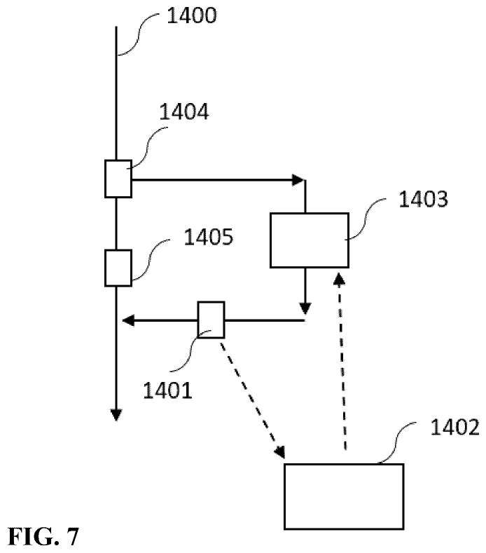

FIG. 7 shows an additional control system used for pump assisted gravity.

An additional control system can be implemented to maximize energy efficiency by turning off a pump unit when not needed. Also, the pump speed can be optimized based on input data from sensors. In a typical implementation, temperature and/or pressure sensors can be deployed to obtain necessary information which can be used for constructing a feedback loop. For example, liquid subcooling, i.e., the temperature difference between the coolant inlet and outlet temperatures at the heat exchanger, can be used for feedback to optimize the volumetric flow rate of the system via controlling the pump speed. When subcooling is small the pump operates at low speed

Referring to FIG. 7, a control system for pump-assisted gravity driven coolant flow can be used. A downcomer pipe 1400 with a parallel fluidic path is equipped with a pressure and/or temperature sensor 1401).

The pressure and/or temperature data can be transmitted to a controller 1402 which determines the ideal pump speed of a positive displacement pump 1403 and sends control signal. If a branching point 1404 and back-flow preventing device 1405 are implemented with actuatable components, a controller unit 1402 also sends control signal to these components.

A pump control system that optimizes pump speed based on predicted coolant mass flow rate, which is derived from machine learning model using input features from at least one of IT equipment and a PDU (Power Distribution Unit).

Coolant mass flow rate can be approximated using CPU power consumption as an input. CPU power consumption can be measured or predicted.

In a typical implementation, absolute pressure or subcooling temperature or both can be maintained throughout the thermosyphon operation by adjusting the pump speed to ensure the onset of coolant boiling is optimized. A control system is also utilized to ensure pump unit can rest as much as possible to extend the lifetime of the pump.

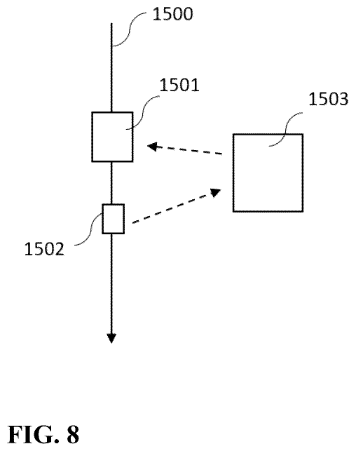

FIG. 8 shows an alternative control system with a peripheral pump.

In an alternative implementation, a pump with an impeller rotating in a concentric channel can be installed in-line with a downcomer. For example, a peripheral pump, also known as regenerative turbine pump, can be implemented.

Since a regenerative turbine pump does not block the coolant flow when turned off, the system implementation can be simplified without a parallel flow path for installing a pump unit. When the system operates under “gravity-mode” the pump is turned off and coolant freely flows through a pump.

When pump is in operation, the control system will evaluate if the pump can be turned off, based on the system performance, to achieve maximize energy efficiency. If a thermosyphon loop can sustain robust coolant circulation without pump, the pump will be turned off to save energy and extend lifetime of the pump. Also, the pump speed can be optimized based on input data from sensors. In a typical implementation, temperature and/or pressure sensors can be deployed to obtain necessary information which can be used for constructing a feedback loop. For example, a subcooling temperature could be used as a proxy to optimize the volumetric flow rate of the system via controlling the pump speed.

FIG. 8 shows a typical implementation of peripheral pump for hybrid (active/passive) CDU. A downcomer pipe 1500 can be equipped with a peripheral pump 1501 and pressure/temperature sensor unit 502. Pressure and/or temperature data is processed in a controller unit 1503 which in turn sends control signal to a pump unit 1501.

When the system runs on “gravity-mode” the pump unit is turned off, while coolant freely flows through the pump unit via gravity. When additional static pressure is necessary to improve the thermosyphon system performance, a pump unit can be activated to add additional static pressure to increase the overall coolant mass flow rate in the system.

Coolant Inventory Management

Optimum amount of coolant must be maintained in a passive thermosyphon system to ensure proper operation of the system. A coolant inventory management consists of a reservoir (“liquid accumulator”) that is placed above an evaporator to ensure enough gravity driven force proportional to the height difference is generated.

Also, the reservoir is located below the outlet of a heat exchanger in such a way that condensing coolant from heat exchanger is drained properly into the reservoir. When a pump unit is implemented, the liquid accumulator is positioned above the pump to ensure that liquid is always flowing through the inlet port of a pump unit to prevent fluid cavitation.

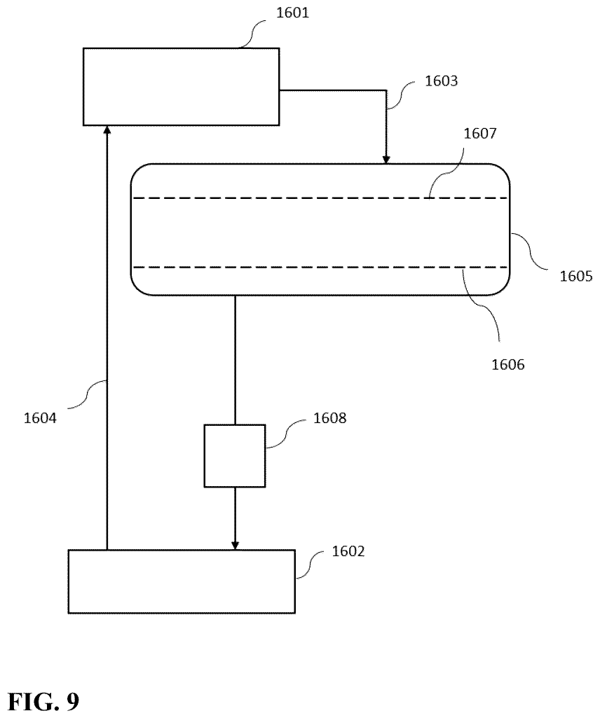

FIG. 9 is a side view of a liquid inventory management system.

In a typical implementation, a heat exchanger/condenser 1601 and one or more evaporators 1602 are fluidically connected with a downcomer pipe 1603 and a riser pipe 1604. When heat is added to evaporator 1602, liquid coolant is displaced and could reach a heat exchanger, leading to non-ideal operating condition with lower heat transfer coefficient.

To prevent the condenser from “flooding”, a component with substantial internal volume, or “liquid accumulator” 1605 can be installed in-line with a downcomer pipe 1603. To ensure proper drainage of condensing liquid to a liquid accumulator, the liquid accumulator can be positioned lower than the outlet port of a heat exchanger, yet ensuring enough distance between evaporator 1602 and liquid accumulator 1605 to have enough static pressure to drive the coolant from within the thermosyphon system.

Throughout the thermosyphon-loop operation, liquid level could fluctuate from low level 1605 under low heat load to high level 1606 under high heat load. The liquid accumulator is sized properly in such a way that the highest liquid level does not reach the heat exchanger. Optional pump unit 1608 can be installed below the liquid accumulator to ensure coolant entering the pump unit is always in liquid phase.

Rack-mount equipment has to be always optimized for minimizing the overall height, since increased height (rack unit) will take up highly valuable rack space that can be otherwise used for adding more computational resources. Therefore, it would be ideal to have a liquid accumulator with an overall form factor that resembles a “pizza box”, with minimum height while ensuring enough internal volume can be provided for storing coolant. Depending on the overall system implementation, the required internal volume can vary, therefore a modular liquid accumulator can be envisioned to minimize manufacturing cost. For example, a modular liquid accumulator can be constructed by brazing or welding parts pre-defined with connector ports.

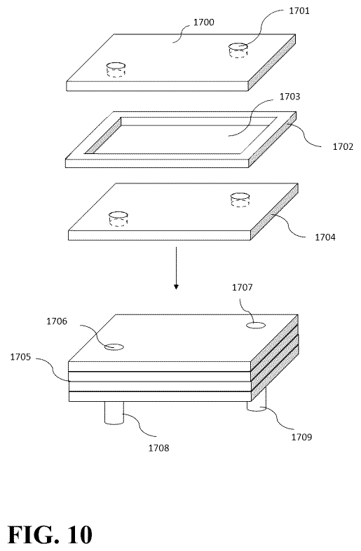

FIG. 10 shows a modular fluid inventory system. Rack-mount equipment has to be always optimized for minimizing the overall height, since increased height (rack unit) will take up highly valuable rack space that can be otherwise used for adding more computational resources. Therefore, it would be ideal to have a liquid accumulator with an overall form factor that resembles a “pizza box”, with minimum height while ensuring enough internal volume can be provided for storing coolant. Depending on the overall system implementation, the required internal volume can vary, therefore a modular liquid accumulator can be envisioned to minimize manufacturing cost. For example, a modular liquid accumulator can be constructed by brazing or welding parts pre-defined with connector ports.

Referring to FIG. 10, a metal plate 1700 with pre-defined holes 1701 can be brazed together with a second part 1702 with recessed or cut-out that defines internal geometry 1703. If these two parts are assembled along with a second metal plate (1704) with varying number of repeats, a modular liquid accumulator 1705 can be constructed with four ports 1706, 1707, 1708, and 1709.

In a typical implementation, one of the top ports 1706 can be fluidically connected to an outlet port of heat exchanger, whereas the second top port 1707m can be fluidically connected with an inlet port of heat exchanger through a capillary tube.

Elevated pressure from liquid vapor mixture can act as a pressure source to ensure the liquid coolant is flushed out properly during thermosyphon operation. If a single fluid distribution manifold is deployed, a bottom port 1708 can be fluidically connected to a downcomer pipe, while the second bottom port 1709 can be capped.

If two fluid distribution manifolds are implemented, a second bottom port 1709 can be fluidically connected to the second manifold. Alternatively, a single part with port and recessed surface can be used to further simplify the manufacturing process.

In typical thermosyphon-based electronics cooling application, non-hermetic seals are introduced to the system, which can potentially lead to minor coolant loss over time. Therefore, it would be advantageous to be able to monitor the coolant inventory within the system.

A minor coolant leak (minor coolant loss) refers to a minor coolant leak by coolant molecule diffusion across non-metallic seals and materials over a long period of time.

A liquid level sensor such as a capacitive sensor can be implemented inside a liquid accumulator to monitor the amount of coolant inside the reservoir. Since the level of coolant inside the reservoir tank dynamically changes depending on the heat load, the ideal level can be determined at different heat loads into the system. The amount of heat load can be determined directly or indirectly from IT equipment via Baseboard Management Controller (BMC) or power distribution unit (PDU). If the liquid level falls below the ideal level, coolant will have to be added to the system.

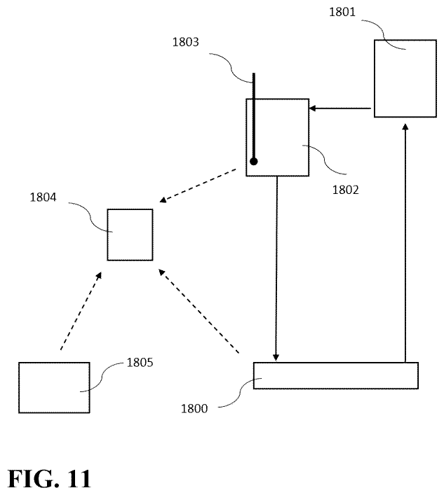

FIG. 11 shows a fluid inventory monitoring system for the invention. In a typical implementation, heat from IT equipment 1800 generates liquid vapor, which in turn is condensed by a heat exchanger 1801. This results in coolant displacement in a liquid accumulator 1802. Throughout the system operation, a liquid level inside a liquid accumulator can be monitored with a sensor 1803.

To determine if the liquid level is properly maintained, additional information such as the amount of heat load from IT equipment should be monitored as well. A controller unit 1804 collects data from IT equipment 1800 or power distribution unit 1805 and compares the actual measurement against expected ideal level. If liquid level drops below a pre-determined safety threshold level, a proper maintenance protocol would have to be executed.

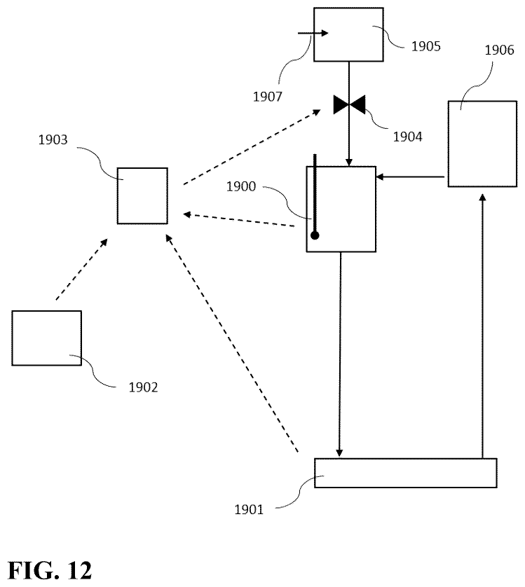

FIG. 12 shows a fluid inventory management system with a reserve tank for easy and straightforward maintenance. To fully streamline a coolant charging protocol as part of the system maintenance protocol, an additional reservoir tank can be added as a reserve. This second tank can be fluidically connected with the main liquid accumulator with a solenoid valve and/or a pump that can transport coolant from a reserve tank to a main liquid accumulator. If a pump is installed between the two tanks, the pump can be also used to remove the coolant from the system if in case changes in the system requirement calls for less amount of coolant in the system.

Referring to FIG. 12, if data from liquid level sensor 1900, IT equipment 1901, and/or power distribution unit 1902 indicates low liquid level, a controller unit 1903 can actuate a valve 1904 such as normally closed solenoid valve that fluidically connects a liquid reservoir 1905 to the rest of the system.

The reservoir is located at the highest elevation, above a heat exchanger 1906 to ensure liquid is drained into the system properly when the valve 1904 is opened. A port 1907 is provisioned on a reservoir tank for charging or discharging. Instead of a fully automated maintenance approach, a manual isolation valve can be implemented instead.

Coolant can leak out of the non-hermetic thermosyphon loop into the atmosphere over time. This would result in lower fluid charging ratio, and therefore decreased thermal performance. Therefore, it is important to monitor any leaks in the system. As part of the leak monitoring system, multiple sensors can be installed throughout the system.

In a typical implementation, live data stream from temperature or chemical sensors (e.g., metal oxide, Infrared, or MEMS-based sensors) can be monitored throughout the operation.

The system can use a refrigerant leak detection system such as the system shown and described in U.S. Pat. No. 6,772,598 to Rinehart, which is incorporated by reference.

The chemical sensors can be used to detect anomalies in the system. Although highly unlikely, if there is a catastrophic failure (i.e., pipe rupture), liquid phase coolant will rapidly leak out to the ambient and start to evaporate. This will result in sudden drop in temperature. Temperature data collected throughout the system can be monitored to capture this behavior to detect accidental coolant leaks.

Refrigerant based cooling system should be designed to contain coolant throughout the operation. However, due to mechanical defects, such as cracks or polymer seal failure, system may lose coolant from the system.

RAnomaly detection algorithms, such as isolation forest, local outlier factor, robust covariance, support vector, or other machine learning methods, could be applied to the data to identify anomalous behavior in the system. If in case any anomalies are detected, such as sudden drop in temperature associated with rapid evaporation of coolant into ambient, maintenance alerts can be triggered to notify system operators.

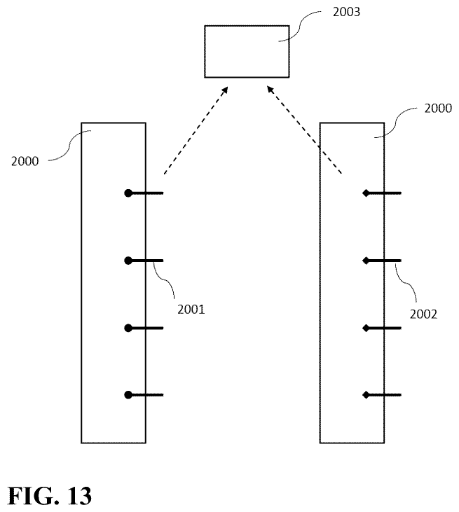

FIG. 13 shows a leak detection system based on a live data stream from sensors. Non-hermetically sealed system 2000 will have sections within the system where coolant leak is more probable “potential leak points”. On or around these locations with higher probability of coolant leak, temperature sensors 2001 and/or chemical sensors 2002 can be installed. A monitoring module 2003 along with anomaly detection analytic methods will flag system anomaly if leak is detected.

If any of the temperature sensors detect sudden drop in temperature due to rapid evaporation of coolant in to ambient, which indicates a major leak, a safety isolation valve can be triggered to contain coolant from leaking into ambient, while IT equipment undergoes through a graceful shutdown sequence.

A major leak can include catastrophic rupture or polymer seal failure that forces the system to be shut down. Major coolant leak will lead to sudden temperature drop that can be used as a proxy for detecting such accident.

A minor leak can include Refrigerant diffusion through polymer seal could potentially lead to slow but steady loss of refrigerant. Despite a minor leak, a cooling system would perform as expected until the amount of coolant in the system drops below required minimum amount.

The use of certain flammable coolants requires chemical sensors (leak detectors) by law for safety reason.

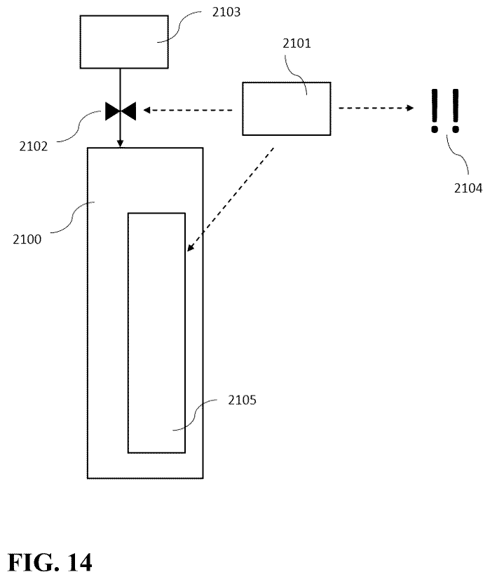

FIG. 14 shows a major leak response system for the pCDU. When a major coolant leak is detected from the system 2100, a control module 2101 actuates the isolation valve (2102 which isolates the pCDU 2103, where vast majority of fluid is stored. Emergency alert 2104 is issued to inform system operators, while IT equipment 2105 undergoes a graceful shutdown, including workload redistribution, to prevent data loss or service outages.

The system can use a water leak detection monitor, for detecting accidental water leaks in or around a heat exchanger. See U.S. Pat. No. 4,835,522 to Andrejasich et al., which is incorporated by reference.

Studies have shown ambient air diffusion into the system could negatively impact the overall cooling performance. For example, air intrusion could cause an increase in thermal resistance or decrease in mass flow rate in the thermosyphon loop (TSL) at a given heat flux. The non-hermetic nature of the thermosyphon loop could cause air to diffuse into the system through potential leak paths such as elastomeric sealants in pipe fittings.

Based on real-time data stream, the software can analyze, monitor, and detect air intrusion into a coolant loop. Anomaly detection algorithms, such as isolation forest, local outlier factor, robust covariance, support vector, or other machine learning methods, could be applied to the data.

To remove diffused air from the system, a small component with a defined internal volume can be positioned at or near the top of the TSL that can act as an air trap. This component can selectively accumulate air over refrigerant vapor. A non-intrusive sensor, such as ultrasonic time-of-flight (Time of Flight) sensor or temperature sensors, can be equipped around the air trap to evaluate and monitor the amount of air trapped. As part of the maintenance procedure, the collected air could be removed by a release mechanism.

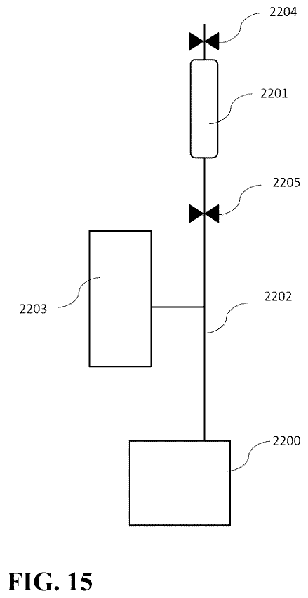

FIG. 15 is a schematic of an air ingress management system for the pCDU. When air ingresses into the system, due to its low density and non-condensable nature, air can be separated from the condensed coolant from liquid coolant reservoir 2200 and will accumulate in a second reservoir 2201 fluidically connected with a downcomer pipe 2202 and positioned at an appropriate elevation, for example above a heat exchanger 2203.

During scheduled maintenance, the air reservoir can be evacuated via an upper access valve 2204 while the lower valve 2205 is closed to prevent loss of working fluid.

### Features Related to CPU/GPU Heat Load Prediction and Analytics

Modern IT equipment supports detailed real time telemetry. For example, the latest server motherboards are equipped with BMC (baseboard management controller), which exposes variety of data related to computing hardware, such as CPU temperature and fan speed, for consumption through industry standard data transfer protocols such as IPMI or Redfish.

Real-time telemetry data provides essential information for data center operators to plan facility upgrades or optimization. However, in colocation facilities, where access to data from IT equipment is not viable, insights derived from such data are lost.

Limited access to IT equipment also poses a challenge to a pCDU which could otherwise ingest real-time data and run predictive analytics to provide end users with operational insights related to the cooling system performance. For example, heat load from CPU/GPU and temperature measurements can be used to predict coolant mass flow rate without costly flow measurement devices.

Coolant mass flow rate can be approximated using CPU power consumption as an input. CPU power consumption can be measured or predicted.

In the absence of heat load information, CPU/GPU heat load can be predicted using machine learning based models using several input features, such as CPU/GPU specifications and data related detailed power consumption, which could be obtained from a “smart” PDU. The machine learning model can be deployed in pCDU installed in co-location data centers to provide operational insights, despite limited access to data from IT equipment.

The system can use prediction models such as the model shown and described in U.S. Pat. No. 10,581,974 to Sustaeta et al., which is incorporated by reference.

A prediction controller can be used to estimate CPU (Central Processing Unit) heat load based on a PDU (Power Distribution Unit), wherein the prediction controller is utilized when data from IT equipment is not accessible. A machine learning model can be used to predict CPU power consumption using time series data from PDU as an input.

Machine learning model will correlate real time power consumption from individual servers to CPU power consumption.

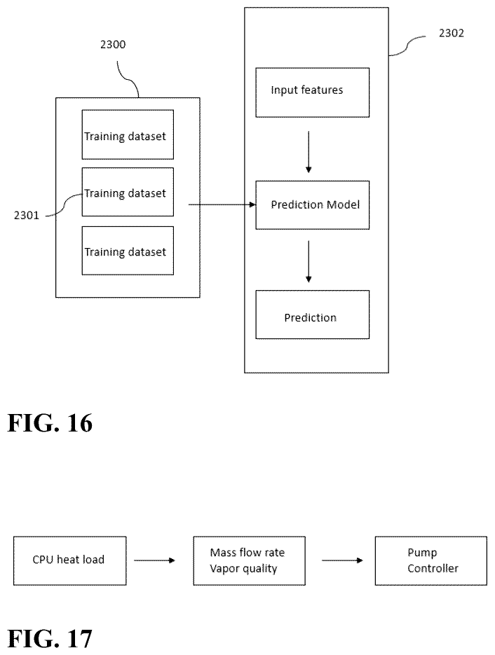

FIG. 16 shows a schematic of a prediction model deployment for the pCDU. where access to data from IT equipment is not feasible.

In a data center environment 2300 where access to real time telemetry data from IT equipment is possible, training datasets can be readily obtained 2301. In an environment where data access is limited, such as colocation data centers 2302, a prediction model can be deployed to predict data related to IT hardware.

A Colocation data center is a facility where IT equipment is owned by individual tenants and the data center only provides cooling/power as a service. Since IT equipment is owned by tenants, data center operators do not have operational visibility in terms of what is going on inside IT equipment.

Consequently, predicted CPU/GPU heat load or actual CPU/GPU heat load based on telemetry data can be further utilized to derive coolant mass flow rate within a thermosyphon loop or vapor quality. These parameters, in turn, can be used to determine if a supplementary pump should be turned on to switch from gravity-driven coolant flow to pump-assisted gravity driven coolant flow to ensure adequate amount of coolant is being circulated to cool computer chips.

FIG. 17 is a schematic of a conditional pump actuation process flow for the pCDU. CPU heat load based on prediction model or direct measurement can be used to derive coolant mass flow rate and vapor quality. These operational parameters can be, in turn, used to trigger a pump in a pCDU, switching the pCDU to operate from gravity driven coolant flow (passive) to pump-assisted gravity driven flow (active).

### Features Related to Monitoring Sustainability Metrics

Unlike air-cooling based systems, liquid/refrigerant cooling systems enable accurate measurement of the amount of waste heat captured in hot water.

A pCDU is provisioned with industry standard energy metering unit (BTU meter), which not only could provide accurate amount of heat being captured in facility-side coolant loop, but also provide the waste heat capture efficiency, based on the heat load to IT equipment through BMC or PDU.

For example, the amount of heat captured can be calculated based on a simple energy balance calculation, whereas the input energy can be extracted from the CPU/GPU heat load or derived from the PDU. The heat capture efficiency can be monitored over time to improve operational energy efficiency. In addition, significant decrease in heat capture efficiency inside a heat exchanger can be used as a proxy to detect heat exchanger fouling.

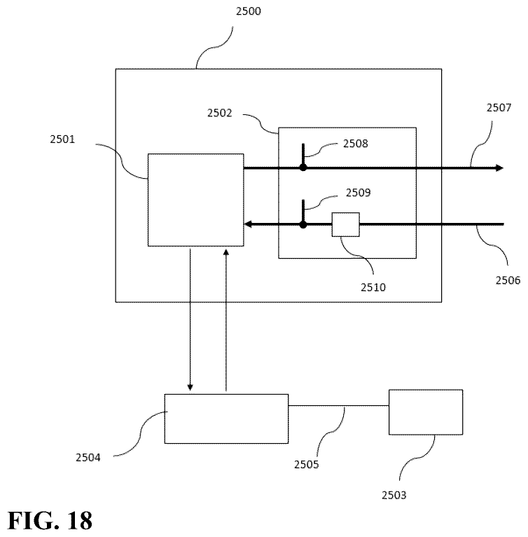

FIG. 18 shows a heat capture monitoring system 2500 for the pCDU. A pCDU is equipped with a heat exchanger 2501 and a heat metering module 2502. In a typical system implementation, a PDU 2503 provides electrical power to IT equipment 2504 through a power transmission line, i.e., power cables 2505.

Heat generated from IT equipment is transferred to facility-side coolant loop inside a heat exchanger 2501. For example, chilled water enters 2506 and warm water exits 250) from a pCDU. Temperature sensors 2508, 2509 and flow meter 2510 inside a BTU meter can calculate the amount of heat transferred to the facility-side coolant loop using the energy balance equation.

The input energy into the heat exchanger can be directly extracted from the heat load from CPU/GPU or derived from a PDU. Monitoring the heat capture efficiency can help data center operators access quantitative information to improve overall operational energy efficiency. In addition, the heat capture efficiency can be used as a proxy to detect heat exchanger fouling.

Data stream related to sustainability, such as heat capture efficiency, can be coupled with an auditable or immutable database, which is an append-only database that cannot be deleted or modified. Coupled with a standards-based metering system from pCDU hardware, the database could be managed, certified, and validated by a third party.

The end-user of the system can develop carbon offset projects based on this end-to-end platform to produce permanent, additional, verified, enforceable, real carbon offsets. The carbon offset can be monetized in the form of carbon tax credit. Software-as-a-Service (SaaS) platform or license-based subscription model can orchestrate the end-to-end process from data generation to streamlined filing carbon credit claims. Metered heat collection and energy capture quantification from computer racks/telecoms shelves for carbon tax credit claims.

Data collected from a PDU (Power Distribution Unit) and the heat exchanger can be used to calculate rack-level heat capture efficiency.

And storage of the data in a database for storing energy in an out of the system for an end-user to monitor and account for carbon offset credit (sustainability accounting). Archiving energy efficiency and carbon offset information can use the technology used in U.S. Pat. No. 8,000,938 to Mcconnell et al., which is incorporated by reference.

### Features to Improve Thermosyphon Loop Start-Up Behavior

To overcome challenges associated with flow instability during a cold start of a two-phase thermosyphon loop (e.g., new deployment or rack-level maintenance), the start-up process may include an active pump to establish a robust flow. However, in case of gravity driven passive thermosyphon loop without a pump, establishing a robust flow under low heat could become quite challenging.

In a typical thermosyphon loop, mass flow rate of low boiling point refrigerants tends to increase as the amount of heat being introduced to the system increases. When a server rack equipped with a two-phase thermosyphon loop-based cooling system is first turned on, heat from IT equipment during cold start may not be substantial enough to reach the ideal condition for the two-phase flow. Moreover, there is the potential for temperature overshoots prior to robust coolant circulation being established. This challenge stems in part from the lack of control of the IT equipment power that is typically defined independently at the server-level.

To mitigate the challenges associated with a cold start-up scenario, it would be advantageous to establish circulation in the thermosyphon loop in a controlled way independent of the thermal power delivered by the servers. Resistive heating elements (localized or distributed) located on the riser(s) and controlled by the pCDU can provide precise amounts of heat into the thermosyphon loop during the system operation, but it is envisioned to be utilized primarily during the initial start-up. When IT equipment turns on and start to provide substantial power beyond the threshold amount of heat, the additional heating element can be turned off automatically. It is worth mentioning that IT equipment at idling state still draws significant amount of power that is well beyond the required amount heat to establish two-phase flow, therefore the resistive element would draw power only during initial start-up or maintenance.

Power delivery to the heaters is controlled by a pCDU using, for example solid state relays packaged into the pCDU and powered by AC or DC power delivered from the rack PDU. During start-up, the heat input to the riser(s) will initiate a stable recirculation of two-phase refrigerant mixture within the thermosyphon loop, while avoiding uncontrolled and unstable flow patterns in the presence of the uncontrolled heat source, e.g., servers/IT hardware.

Once the control system, e.g., pCDU, detects robust two-phase flow and the servers are operating, the heater turns off automatically to improve energy efficiency of the system. A specific example of an implementation is shown in a figure below. Here the starter heaters are located at the bottom of the riser where the static pressure is the greatest.

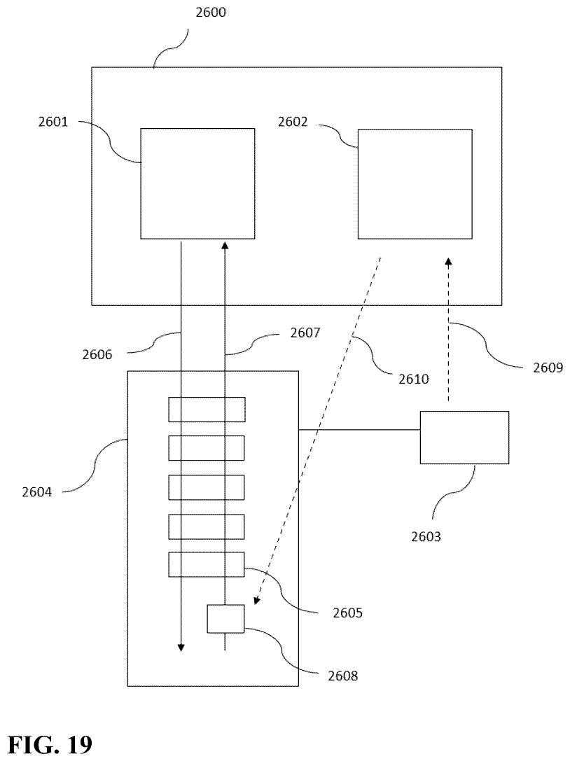

FIG. 19 is a schematic of a feature that improves the thermosyphon-loop start up behavior for a pCDU. A pCDU 2600 has a heat exchanger 2601 and a control module 2602. A PDU 2603 provides electrical power to a server rack 2604 with multiple servers 2605.

Each server can be fluidically connected with a heat exchanger via a downcomer pipe 2606 and a riser pipe 2607 forming a thermosyphon loop. A heating element 2608 can be installed at the bottom of the riser. When servers are first turned on with little heat load into the thermosyphon loop, flow instability can occur.

PDU power draw can be monitored 2609 to detect the moment when servers are initially turned on. The control module 2602 could activate the heating element 2608 through a control signal 2610 to provide sufficient coolant driving force by generating liquid vapor mixture in the riser column. When the system establishes robust coolant circulation, the heater can be turned off.

In addition, it would be advantageous to establish circulation in the thermosyphon loop in a controlled way by precisely controlling the start-up sequence of servers in a rack. In a thermosyphon loop-based cooling system, a server at the bottommost position would have the greatest static pressure head to aid the stable flow within the thermosyphon loop, and therefore is relatively more advantageous than any servers above to initiate the two-phase flow.

As the mass flow rate slowly increases during the early start-up, a microcontroller in a pCDU could orchestrate the start-up process by communicating with the power distribution unit to power on servers starting from bottom and progressing upwards to the top, while taking threshold mass flow rate as an input to trigger sequence of events precisely.

Once a stable coolant flow is established, the overall system becomes resilient to external perturbations, such as fluctuations in heat flux caused by changing computational demands. This process can be executed with or without Data Center Infrastructure Management (DCIM) software or Data Center Management (DCM) software.

A resistive heating element (2608) provides thermal energy to circulate coolant in a thermosyphon loop.

The system can use a server start-up detection and heater block starter feature. When a server rack is turned on, computer servers start to draw electrical power from a PDU (power distribution unit). This initial “start-up” can be detected by simply monitoring the PDU usage. A control module can detect “start-up” and trigger a heater block to turn on. The heater block provides thermal energy to a thermosyphon loop to generate coolant circulation. Once control module detects a substantial coolant flow circulation, the heater block is turned off as thermal energy from computer chips provide adequate heat to sustain the flow.

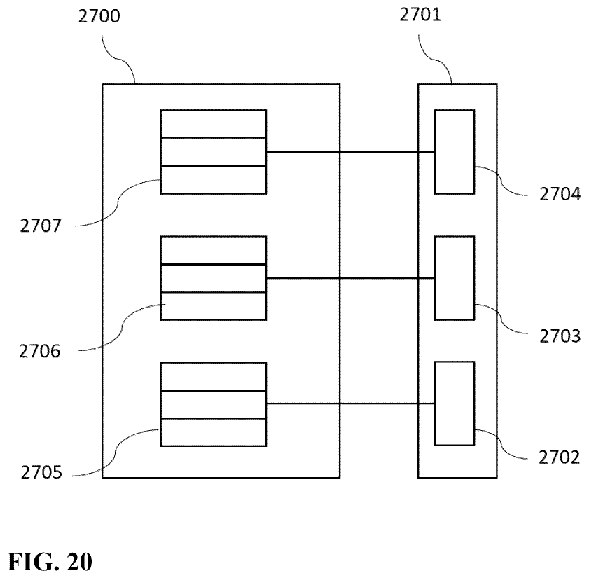

FIG. 20 is a schematic representation of a server rack start up sequence for the pCDU. Start up sequence can be orchestrated by sequentially turning the servers from bottom to top. For example, as servers from a server rack 2700 turn on, a PDU 2701, comprising three power banks 2702, 2703, and 2704), can provide power to the bottommost server group 2705, by activating a power bank 2702.

The bottom server group 2705 which has the greatest static pressure head can aid the onset of stable annular two-phase flow in a thermosyphon loop.

As mass flow rate increases and further making the passive two-phase thermosyphon loop robust, other power banks 2703 can be turned on to provide power to a middle server group 2706. Finally, the last server group 2707 can be turned on.

The system can use flow stabilization methods during start-up (with PDU)

In addition, it would be advantageous to establish circulation in the thermosyphon loop in a controlled way by precisely controlling the start-up sequence of servers in a rack. In a thermosyphon loop-based cooling system, a server at the bottommost position would have the greatest static pressure head to aid the stable flow within the thermosyphon loop, and therefore is relatively more advantageous than any servers above to initiate the two-phase flow. As the mass flow rate slowly increases during the early start-up, a microcontroller in a pCDU could orchestrate the start-up process by communicating with the power distribution unit to power on servers starting from bottom and progressing upwards to the top, while taking threshold mass flow rate as an input to trigger sequence of events precisely. Once a stable coolant flow is established, the overall system becomes resilient to external perturbations, such as fluctuations in heat flux caused by changing computational demands. This process can be executed with or without Data Center Infrastructure Management (DCIM) software or Data Center Management (DCM) software.

### System Optimization Through Heat Load Balancing on the Secondary Side

In heat reuse applications, the thermal load from the IT equipment and the heat reuse demand may not always be well matched. For example, rejecting all the heat from the IT equipment to a space heating application may only be feasible under certain environmental conditions, e.g., in winter, but not summer.

However, deploying IT equipment based on the baseline heat requirements may be too restrictive for deployments. Moreover, the heat reuse application may require a well-controlled supply temperature.

To mitigate this issue, it is advantageous to have control of the secondary loop working fluid supply temperature and the secondary side fluid flow rate through the condenser. The supply temperature from the heat reuse application to the IT equipment racks is set to a maximum value at the design stage.

However, when the heat reuse load is small, the supply temperature could exceed the specified maximum value. By provisioning a centralized liquid/liquid heat exchanger, heat can be shunted to the facility loop (e.g., dry cooler or chiller) to maintain the supply temperature within spec. At the same time, server utilization and, thus heat load, on a rack basis can fluctuate in time.

In order to ensure the design specified return temperature to the heat reuse application, a fail-open automated valve controlled by the pCDU can be provided at the inlet to the condenser on the secondary side to reduce the flow rate through the condenser when server utilization and thus heat load is low.

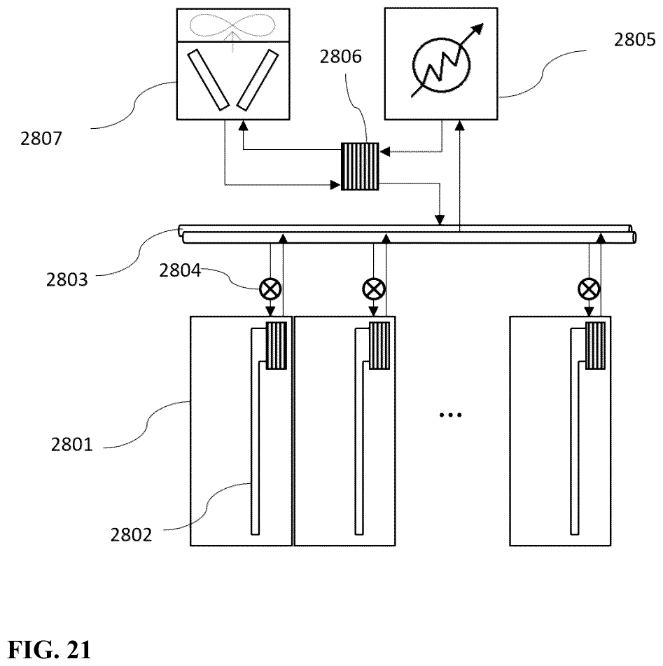

FIG. 21 is a schematic for system optimization through heat load balancing on the secondary side for the pCDU.

The IT equipment racks 2801 incorporate a primary cooling loop 2802 that interfaces to a facility level secondary loop manifold 2803. An automated valve 2804 controlled by the pCDU adjusts the flow of the secondary flow through the condenser to ensure the temperature leaving the condenser on the secondary side is consistent with the heat reuse application 2805 requirements.

A liquid/liquid heat exchanger 2806 is provided for supplemental heat rejection to, for example, a variable speed pumped dry cooler loop 2807 with sufficient capacity to reject the design IT heat load that is controlled to achieve a specified secondary side supply temperature to the IT equipment racks.

Although specific advantages have been enumerated above, various embodiments may include some, none, or all of the enumerated advantages.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

The term “approximately” is similar to the term “about” and can be +/−10% of the amount referenced. Additionally, preferred amounts and ranges can include the amounts and ranges referenced without the prefix of being approximately.

While the invention has been described, disclosed, illustrated and shown in various terms of certain embodiments or modifications which it has presumed in practice, the scope of the invention is not intended to be, nor should it be deemed to be, limited thereby and such other modifications or embodiments as may be suggested by the teachings herein are particularly reserved especially as they fall within the breadth and scope of the claims here appended.

1. A passive coolant distribution unit (pCDU) system, comprising:
a heat exchanger;
a coolant distribution manifold;
a fluid inventory management system between the heat exchanger and the coolant distribution manifold, for allowing condensed liquid to accumulate in a fluid inventory storage unit;
a supplementary positive displacement pump downstream to the fluid inventory storage unit; and
sensors selected from at least one temperature sensor and at least one pressure sensor, the sensors providing a feedback loop for maintaining a liquid level in the fluid inventory storage unit.

2. The passive coolant distribution unit (pCDU) system of claim 1, further comprising:
a chassis for housing the pCDU system, the chassis having detachable brackets for installing the chassis adjacent to a computer server rack.

3. The passive coolant distribution unit (pCDU) system of claim 1, further comprising:
a second coolant distribution manifold; and
quick connects for adding the second coolant distribution manifold to the passive coolant distribution unit (pCDU) system.

4. The passive coolant distribution unit (pCDU) system of claim 1, further comprising:
a pump unit for providing a thermosyphon loop in the system.

5. The passive coolant distribution unit (pCDU) system of claim 4, wherein the pump unit is installed fluidically in parallel to a main liquid coolant flow path in the system.

6. The passive coolant distribution unit (pCDU) system of claim 4, further comprising:
a backflow preventer to stop pumped liquid from returning to the fluid inventory storage unit.

7. The passive coolant distribution unit (pCDU) system of claim 4, wherein the fluid inventory management system includes:
a level sensor that ensures coolant level is maintained at a selected level, to prevent fluid cavitation in the pump unit.

8. The passive coolant distribution unit (pCDU) system of claim 1, wherein the fluid inventory management system includes: a modular and stackable liquid accumulator.

9. The passive coolant distribution unit (pCDU) system of claim 1, further comprising:
a reserve tank fluidically connected to the fluid inventory management system; and
a valve for allowing coolant fluid to be transported to a main accumulator in the fluid inventory management system.

10. The passive coolant distribution unit (pCDU) system of claim 1, further comprising:
a leak detection monitor, for detecting sudden drop in temperature from temperature sensors in the system, which constitutes a major leak; and
a safety isolation valve triggered by the leak detection monitor to contain coolant from leaking out.

11. The passive coolant distribution unit (pCDU) system of claim 1, further comprising:
a leak detection monitor for detecting data from chemical sensors for detecting coolant leak from the system, the chemical sensors, selected from at least one of metal oxide, Infrared, and MEMS-based sensors, the chemical sensors are useful to detect minor leaks which include small leaks (mostly due to diffusion of coolant molecules through polymer seals) that does not immediately affect overall system performance.

12. The passive coolant distribution unit (pCDU) system of claim 1, further comprising:
a control module for actuating an isolation valve when a major leak, which includes a sudden drop in temperature is detected in the system to contain coolant from leaking out; and
an emergency alert generated from the control module to inform system operators of the major leak detection to provide a shut down of the system.

13. The passive coolant distribution unit (pCDU) system of claim 1, further comprising:
an air ingress management control for separating air ingresses into the system, and accumulating the separated air ingresses into a second fluid inventory storage unit.

14. The passive coolant distribution unit (pCDU) system of claim 1, further comprising:
a prediction controller to estimate CPU (Central Processing Unit) heat load based on PDU (Power Distribution Unit), wherein the prediction controller is used when data from IT equipment is not accessible.

15. The passive coolant distribution unit (pCDU) system of claim 1, further comprising:
a pump control system that optimizes pump speed based on predicted coolant mass flow rate, which is derived from machine learning model using input features from at least one of IT equipment and a PDU (Power Distribution Unit).

16. The passive coolant distribution unit (pCDU) system of claim 1, further comprising:
data collected from a PDU (Power Distribution Unit) and the heat exchanger to calculate rack-level heat capture efficiency; and
storage of the data in a database for storing energy in an out of the system for an end-user to monitor and account for carbon offset credit (sustainability accounting).

17. The passive coolant distribution unit (pCDU) system of claim 1, further comprising:
server start-up detection and heater block starter feature

18. The passive coolant distribution unit (pCDU) system of claim 1, further comprising:
Flow stabilization methods during start-up (with PCDU)

19. The passive coolant distribution unit (pCDU) system of claim 1, further comprising:
load balancing in heat reuse applications, where the demand load fluctuates in time, to ensure sufficient heat rejection from the target equipment to be cooled, e.g., IT equipment, servers

20. The passive coolant distribution unit (pCDU) system of claim 1, further comprising:
a water leak detection monitor, for detecting accidental water leaks in or around a heat exchanger.
